(19) United States
(12) Patent Application Publication
(10) Pub. No.: US 2026/0107542 A1
(43) Pub. Date: Apr. 16, 2026

(54) METHOD FOR MANUFACTURING SEMICONDUCTOR DEVICE

(71) Applicant: SAMSUNG ELECTRONICS CO., LTD., Suwon-si (KR)

(72) Inventors: Young In KIM, Suwon-si (KR); Ji Hoon PARK, Suwon-si (KR); Jin-Woo BAE, Suwon-si (KR); Seung Yong YU, Suwon-si (KR); In Hak JEON, Suwon-si (KR); Byung Soo JOO, Suwon-si (KR)

(73) Assignee: SAMSUNG ELECTRONICS CO., LTD., Suwon-si (KR)

(21) Appl. No.: 19/254,812

(22) Filed: Jun. 30, 2025

(30) Foreign Application Priority Data
Oct. 10, 2024 (KR) 10-2024-0137314

(51) Int. Cl. H10D 64/01; H01L 23/544; H10B 12/00; H10D 64/27

(52) U.S. Cl. CPC H10D 64/027; H10B 12/053; H10D 64/015; H10W 46/00; H10B 12/488; H10D 64/513; H10W 46/301; H10W 46/503

(57) ABSTRACT

A method for manufacturing a semiconductor device, including: providing a substrate including an element region and a scribe lane region; forming a first mask pattern on the element region of the substrate, and a spacer on a side face of the first mask pattern; forming a mask film that extends along the first mask pattern, the spacer, and the substrate, wherein the mask film includes a stepped portion on the scribe lane region of the substrate; forming a sacrificial pattern filling the stepped portion; forming a second mask pattern by etching the mask film to expose the first mask pattern and the spacer; removing the spacer and the sacrificial pattern; and forming a gate trench inside the substrate using the first mask pattern and the second mask pattern as etching masks

### CROSS-REFERENCE TO RELATED APPLICATIONS

This application is based on and claims priority under 35 U.S.C. § 119 to Korean Patent Application No. 10-2024-0137314, filed on Oct. 10, 2024, in the Korean Intellectual Property Office, the disclosure of which is incorporated by reference herein in its entirety.

### BACKGROUND OF THE DISCLOSURE

### 1. Field

The present disclosure relates to a method for manufacturing a semiconductor device, and more particularly to a method for manufacturing a semiconductor device including a buried channel array transistor (BCAT) in which a plurality of word lines are buried in a substrate.

### 2. Description of Related Art

As semiconductor elements become more highly integrated, individual circuit patterns are becoming finer to implement more semiconductor elements in the same area. For example, as an integration degree of the semiconductor elements increases, design rules associated with the components of the semiconductor elements may decrease.

However, in highly scaled semiconductor elements, a process of forming a plurality of gate electrodes and contacts connected to the plurality of gate electrodes may become increasingly complex and difficult.

### SUMMARY OF THE DISCLOSURE

Provided is a method for manufacturing a semiconductor device that protects a key pattern and improves patterning defects of a gate trench.

However, aspects of the present disclosure are not restricted to the one set forth herein. Additional aspects will be set forth in part in the description which follows and, in part, will be apparent from the description, or may be learned by practice of the presented embodiments.

In accordance with an aspect of the disclosure, a method for manufacturing a semiconductor device includes: providing a substrate including an element region and a scribe lane region; forming a first mask pattern on the element region of the substrate, and a spacer on a side face of the first mask pattern; forming a mask film that extends along the first mask pattern, the spacer, and the substrate, wherein the mask film includes a stepped portion on the scribe lane region of the substrate; forming a sacrificial pattern filling the stepped portion; forming a second mask pattern by etching the mask film to expose the first mask pattern and the spacer; removing the spacer and the sacrificial pattern; and forming a gate trench inside the substrate using the first mask pattern and the second mask pattern as etching masks.

In accordance with an aspect of the disclosure, a method for manufacturing a semiconductor device includes: providing a substrate including a scribe lane region, wherein the scribe lane region includes a first region and a second region; forming a first mask pattern on the first region of the substrate, and a spacer on a side face of the first mask pattern; forming a mask film on the first mask pattern, the spacer, and the substrate, wherein the mask film includes a stepped portion on the second region of the substrate; forming a sacrificial pattern filling the stepped portion; patterning the mask film to form a second mask pattern; removing the sacrificial pattern and the spacer; and forming a trench inside the substrate using the first mask pattern and the second mask pattern as etching masks.

In accordance with an aspect of the disclosure, a method for manufacturing a semiconductor device includes: providing a substrate including an element region and a key region; forming a first mask pattern on the element region of the substrate, and a spacer on a side face of the first mask pattern; forming a mask film that extends along the first mask pattern, the spacer, and the substrate, wherein the mask film includes a stepped portion on the key region of the substrate; forming a sacrificial film filling the stepped portion on the mask film; performing a planarization process on the sacrificial film and the mask film to form a sacrificial pattern; patterning the mask film to form a second mask pattern; removing the sacrificial pattern and the spacer; forming a third mask pattern on the key region, wherein the third mask pattern exposes the element region; forming a gate trench inside the substrate using the first mask pattern, the second mask pattern, and the third mask pattern as etching masks; forming a gate insulating film along the gate trench; and forming a gate electrode layer and a gate capping layer on the gate insulating film.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a diagram showing a substrate on which semiconductor devices are integrated, according to embodiments;

FIG. 2 is an enlarged view of a region R1 of FIG. 1, according to embodiments;

FIG. 3 is an enlarged view of a region R2 of FIG. 1, according to embodiments;

FIG. 4 is an enlarged view of a region R3 of FIG. 1, according to embodiments;

FIG. 5 is a cross-sectional view taken along A-A′ of FIG. 4, according to embodiments;

FIG. 6 is a cross-sectional view taken along B-B′ of FIG. 4, according to embodiments;

FIG. 7 is a cross-sectional view taken along C-C′ of FIG. 4, according to embodiments;

FIGS. 8 to 22 are diagrams for explaining a method for manufacturing a semiconductor device, according to embodiments; and

FIG. 23 is a diagram for explaining the method for manufacturing a semiconductor device, according to embodiments.

### DETAILED DESCRIPTION OF THE INVENTION

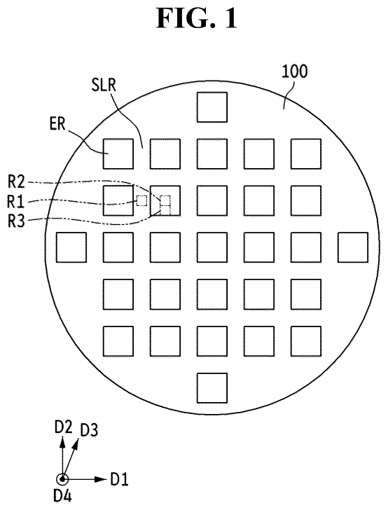

FIG. 1 is a diagram showing a substrate on which semiconductor devices may be integrated, according to embodiments.

Referring to FIG. 1, a substrate 100 may include element regions ER and scribe lane regions SLR in which semiconductor chips are each formed.

The substrate 100 may be at least one of a bulk silicon substrate, a silicon-on-insulator (SOI) substrate, a germanium substrate, a germanium-on-insulator (GOI) substrate, a silicon-germanium substrate, and a substrate of an epitaxial thin film acquired by performing a selective epitaxial growth (SEG).

According to embodiments, a first direction D1, a second direction D2, and a third direction D3 may be directions parallel to an upper face of the substrate 100. The first direction D1 may be orthogonal to the second direction D2. The third direction D3 may form an angle (e.g., an arbitrary angle) with respect to the first direction D1 and the second direction D2. A fourth direction D4 may be orthogonal to the first direction D1, the second direction D2, and the third direction D3. The fourth direction D4 may be a direction perpendicular to the upper face of the substrate 100.

Element regions ER may be arranged two-dimensionally along the first direction D1 and the second direction D2. Each element region ER may be surrounded by a scribe lane region SLR. For example, the scribe lane region SLR may be disposed between the element regions ER adjacent to each other in the first direction D1, and between the element regions ER adjacent to each other in the second direction D2. The scribe region SLR may be disposed around the element region ER. For example, the scribe region SLR may be around the element regions ER and between each element region ER and adjacent element regions ER.

After the semiconductor process is completed, the scribe lane region SLR may be cut to separate the element regions ER into each die. When the substrate 100 is cut into chips, the scribe region SLR may be at least one of partially lost and entirely lost by dicing.

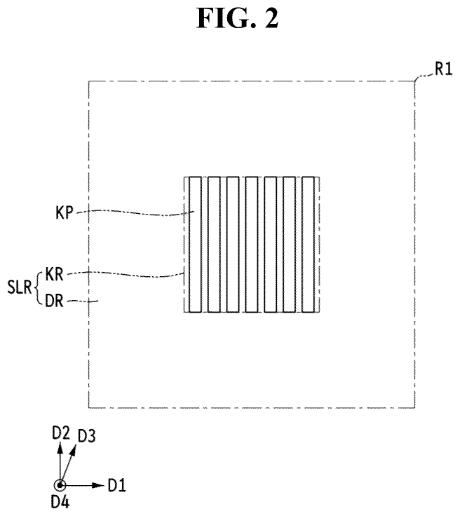

FIG. 2 is an enlarged view of a region R1 of FIG. 1, according to embodiments.

Referring to FIG. 2, in some embodiments, the scribe lane region SLR may include a key region KR and a dummy region DR.

The key region KR may be a region in which a key pattern KP is disposed. The key pattern KP may be at least one of an alignment key and an overlay key. The number and shape of the key patterns KP are not limited to the examples illustrated in FIG. 2. The position and number of the key regions KR in the scribe lane region SLR are not limited to the examples illustrated in FIG. 2. The dummy region DR may be a region in which the key pattern KP is not disposed. The dummy region DR may be a region in which a dummy pattern is disposed.

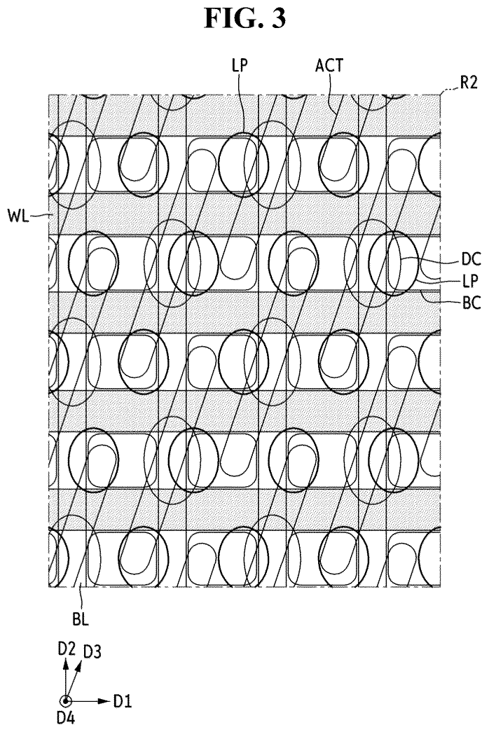

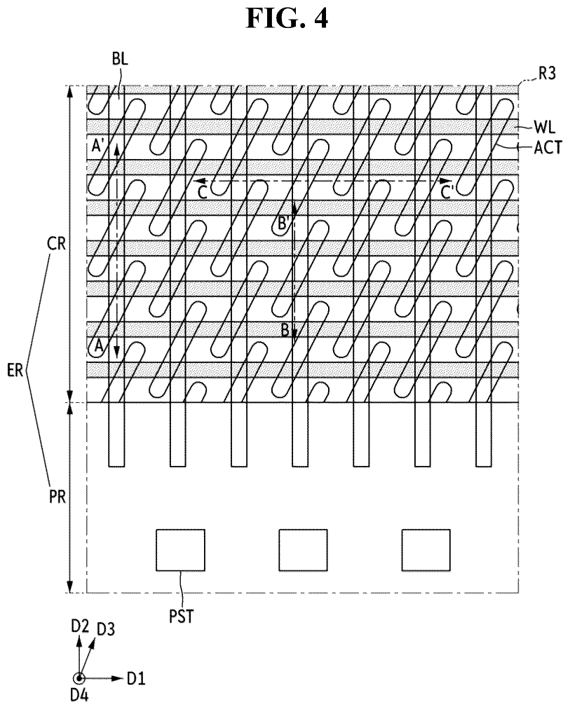

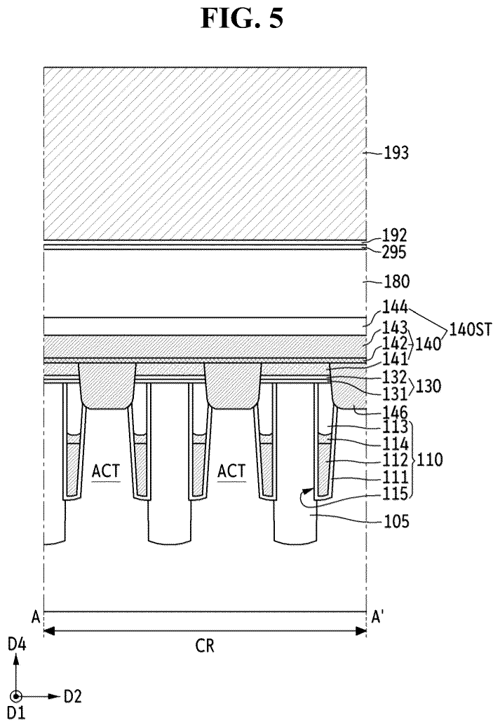

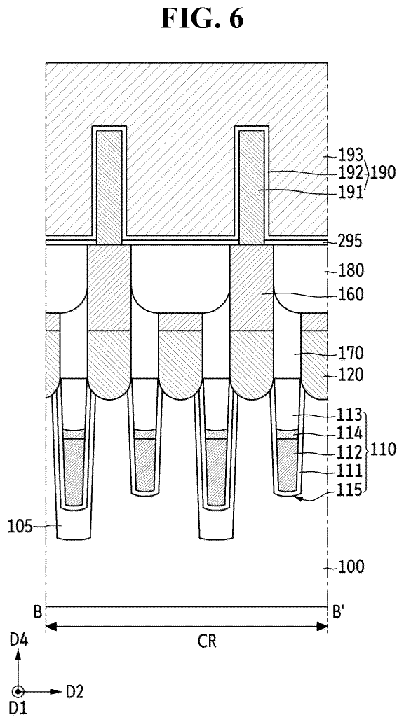

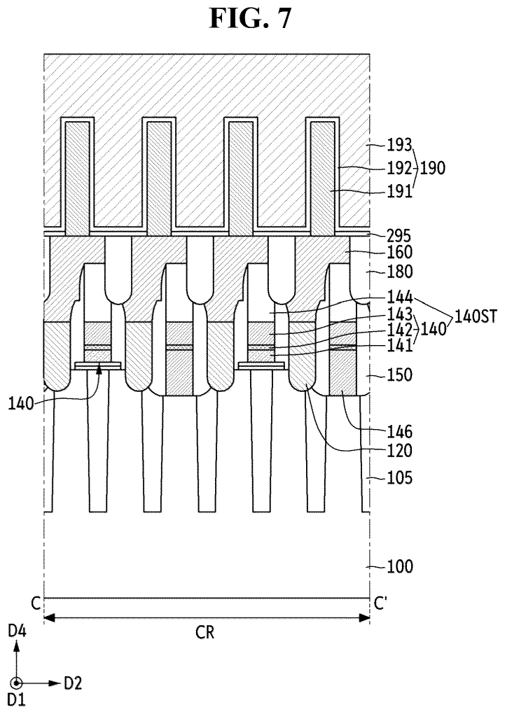

FIG. 3 is an enlarged view of a region R2 of FIG. 1. FIG. 4 is an enlarged view of a region R3 of FIG. 1. FIG. 5 is a cross-sectional view taken along line A-A′ of FIG. 4. FIG. 6 is a cross-sectional view taken along line B-B′ of FIG. 4. FIG. 7 is a cross-sectional view taken along line C-C′ of FIG. 4.

Referring to FIGS. 3 and 4, in some embodiments, the element region ER may include a cell region CR and a peripheral region PR. The cell region CR may be a region in which memory cells are disposed. The peripheral region PR may be disposed around the cell region CR. The peripheral region PR may be disposed between the cell region CR and the scribe lane region SLR. At least one peripheral element PST may be disposed in the peripheral region PR. The position and number of the peripheral element PST are not limited to the examples illustrated in FIGS. 3 and 4.

The cell region CR may include a plurality of cell active regions ACT. The cell active regions ACT may be defined by an element isolation film 105 formed in the substrate 100. As the design rule of the semiconductor memory device decreases, the cell active regions ACT may be disposed in a bar shape of a diagonal line or an oblique line, as shown. For example, the cell active regions ACT may extend in the third direction D3.

A plurality of gate electrodes may extend in the first direction D1 across the cell active regions ACT. The plurality of gate electrodes may extend parallel to each other. The plurality of gate electrodes may be, for example, a plurality of word lines WL. The word lines WL may be disposed at equal intervals. A width of the word lines WL or an interval between the word lines WL may be determined according to a design rule. The conductive lines included in the cell gate structure 110 may be the word lines WL.

Each cell active region ACT may be divided into three portions by two word lines WL extending in the first direction D1. The cell active region ACT may include a bit line connecting region and a memory connecting region. The bit line connecting region may be located in a center portion of the cell active region ACT, and the memory connecting region may be located at an end portion of the cell active region ACT.

A plurality of bit lines BL extending in the second direction D2 orthogonal to the word lines WL may be disposed on the word lines WL. The plurality of bit lines BL may extend parallel to each other. The bit lines BL may be disposed at equal intervals. At least one of a width of the bit lines BL and an interval between the bit lines BL may be determined according to the design rule.

A semiconductor memory device according to some embodiments may include contact arrangements formed on the cell active region ACT. The contact arrangements may include, for example, a direct contact DC, a buried contact BC, and a landing pad LP.

Here, the direct contact DC may refer to a contact that electrically connects the cell active region ACT to the bit line BL. The buried contact BC may refer to a contact that connects the cell active region ACT to the lower electrode 191 of a data storage pattern 190. A contact area between the buried contact BC and the cell active region ACT may be small due to a layout structure. Therefore, a conductive landing pad LP may be introduced to enlarge the contact area with the cell active region ACT and to enlarge the contact area with the lower electrode 191.

The landing pad LP may be disposed between the cell active region ACT and the buried contact BC, or may be disposed between the buried contact BC and the lower electrode 191. In the semiconductor memory device according to some embodiments, the landing pad LP may be disposed between the buried contact BC and the lower electrode of the data storage pattern 190. The contact resistance between the cell active region ACT and the capacitor lower electrode may be reduced, by enlarging the contact area through the introduction of the landing pad LP.

The direct contact DC may be connected to the bit line connecting region. The buried contact BC may be connected to the storage connecting region. Because the buried contact BC is disposed at both end portions of the cell active region ACT, the landing pad LP may be disposed to partially overlap the buried contact BC to be adjacent to both ends of the cell active region ACT. For example, the buried contact BC may be formed to overlap the cell active region ACT and the element isolation film 105 between the adjacent word line WL and the adjacent bit line BL.

The word line WL may be formed as a structure buried inside the substrate 100. The word line WL may be disposed across the cell active region ACT between the direct contact DC and the buried contact BC. As shown in FIGS. 3 and 4, two word lines WL may be disposed to cross one cell active region ACT. As the cell active region ACT extends along the third direction D3, the word line WL may have an angle of less than 90 degrees with the cell active region ACT.

The direct contacts DC and the buried contacts BC may be disposed symmetrically. As a result, the direct contacts DC and the buried contacts BC may be disposed on a straight line along the first direction D1 and the second direction D2.

However, unlike the direct contacts DC and the buried contacts BC, the landing pads LP may be disposed in zigzags in the second direction D2 in which the bit lines BL extend. Also, the landing pads LP may be disposed to overlap the same side face portions of each bit line BL in the first direction D1 in which the word lines WL extend.

For example, each of the landing pads LP of a first line may overlap a left side face of the corresponding bit line BL, and each of the landing pads LP of a second line may overlap a right side face of the corresponding bit line BL.

According to embodiments, the semiconductor memory device may include a cell active region ACT, a plurality of cell gate structures 110, a plurality of cell conductive lines 140, a plurality of storage pads 160, a data storage pattern 190. In some embodiments, the semiconductor memory device may include a plurality of cell gate plugs.

The plurality of cell gate structures 110, a plurality of bit line structures 140ST, the plurality of storage pads 160, and the data storage pattern 190 may be disposed in the cell region CR.

The element isolation film 105 may be formed inside the substrate 100 of the cell region CR. The element isolation film 105 may have a shallow trench isolation (STI) structure having excellent device isolation characteristics.

The element isolation film 105 may define a cell active region ACT inside the cell region CR. The cell active region ACT defined by the element isolation film 105 may have a long island shape including a short axis and a long axis.

The cell active region ACT may have a diagonal shape to have an angle of less than 90 degrees with respect to the word line WL disposed in the element isolation film 105. The cell active region ACT may have a diagonal shape to have an angle of less than 90 degrees with respect to the bit line BL formed on the element isolation film 105.

For example, the cell active region ACT may have a diagonal shape to have an angle of less than 90 degrees with respect to the cell gate structure 110 disposed inside the element isolation film 105. The cell active region ACT may have a diagonal shape to have an angle of less than 90 degrees with respect to the bit line structure 140ST formed on the element isolation film 105.

The element isolation film 105 may include, for example, at least one of a silicon oxide film, a silicon nitride film, and a silicon oxynitride film, but embodiments are not limited thereto. Although examples are illustrated in which the element isolation film 105 is formed of one insulating film, this is only for convenience of explanation, and embodiments are not limited thereto. Depending on the width of the element isolation film 105, the element isolation film 105 may be formed of one insulating film or a plurality of insulating films.

Although examples are illustrated in which the upper face of the element isolation film 105 and the upper face of the substrate 100 are placed on the same plane, this is only for convenience of explanation, and embodiments are not limited thereto.

A plurality of cell gate structures 110 may be disposed inside the cell region CR. Each cell gate structure 110 may be formed inside the substrate 100 and the element isolation film 105. The cell gate structure 110 may be formed across the element isolation film 105 and the cell active region ACT defined by the element isolation film 105.

The cell gate structure 110 may include a cell gate trench 115 disposed inside the substrate 100 and the element isolation film 105, a cell gate insulating film 111, a cell gate electrode 112, a cell gate capping pattern 113, and a cell gate capping conductive film 114. Here, the cell gate electrode 112 may correspond to the word line WL. In some embodiments, the cell gate structure 110 may not include the cell gate capping conductive film 114.

The cell gate trench 115 may be relatively deep in the element isolation film 105, and may be relatively shallow in the cell active regions ACT. A bottom face of the cell gate electrode 112 may be curved. For example, the depth of the cell gate trench 115 inside the element isolation film 105 may be greater than the depth of the cell gate trench 115 in the cell active region ACT.

The cell gate insulating film 111 may extend along the side wall and the bottom face of the cell gate trench 115. The cell gate insulating film 111 may extend along at least a part of the profile of the cell gate trench 115. The cell gate insulating film 111 may include, for example, at least one of silicon oxide, silicon nitride, silicon oxynitride, and a high dielectric constant material having dielectric constant that is higher than a dielectric constant of silicon oxide. The high dielectric constant material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and combinations thereof.

The cell gate electrode 112 may be disposed on the cell gate insulating film 111. The cell gate electrode 112 may fill a part of the cell gate trench 115. The cell gate capping conductive film 114 may extend along an upper face of the cell gate electrode 112. In the semiconductor memory device according to some embodiments, the cell gate capping conductive film 114 may cover the entire upper face of the cell gate electrode 112, but embodiments are not limited thereto.

The cell gate electrode 112 may include a conductive material, for example, at least one of a doped polysilicon, a conductive metal nitride, a conductive metal silicon nitride, a metal carbonitride, a conductive metal silicide, a conductive metal oxide, a two-dimensional material, a metal, and a metal alloy. The cell gate capping conductive film 114 may include, for example, polysilicon or polysilicon-germanium, but embodiments are not limited thereto.

The cell gate capping pattern 113 may be disposed on the cell gate electrode 112 and the cell gate capping conductive film 114. The cell gate capping pattern 113 may fill the cell gate trench 115 that remains after the cell gate electrode 112 and the cell gate capping conductive film 114 are formed. Although examples are illustrated in which the cell gate insulating film 111 extends along the side wall of the cell gate capping pattern 113, embodiments are not limited thereto.

The cell gate capping pattern 113 may include, for example, at least one of silicon nitride (SiN), silicon oxynitride (SiON), silicon oxide (SiO₂), silicon carbonitride (SiCN), silicon oxycarbonitride (SiOCN), and combinations thereof.

In some embodiments, an impurity-doped region may be formed on at least one side of the cell gate structure 110. The impurity-doped region may be a source/drain region of a transistor. The impurity-doped region may be formed in the storage connecting region and the bit line connecting region.

The bit line structure 140ST may include a cell conductive line 140 and a cell line capping film 144. The bit line structure 140ST may include a cell conductive line 140 and a cell line capping film 144. The cell conductive line 140 may be disposed on the substrate 100 and the element isolation film 105 on which the cell gate structure 110 is disposed.

The cell conductive line 140 may extend in the second direction D2. The cell conductive line 140 may intersect the element isolation film 105 and the cell active region ACT defined by the element isolation film 105. Here, the cell conductive line 140 may correspond to the bit line BL.

The cell conductive line 140 may be a multi-layer film. The cell conductive line 140 may include, for example, a first cell conductive film 141, a second cell conductive film 142, and a third cell conductive film 143. The first to third cell conductive films 141, 142, and 143 may be sequentially stacked on the substrate 100 and the element isolation film 105. Although examples are illustrated in which the cell conductive line 140 is a triple film, embodiments are not limited thereto.

Each of the first to third cell conductive films 141, 142, and 143 may include at least one of an impurity-doped semiconductor material, a conductive silicide compound, a conductive metal nitride, a two-dimensional (2D) material, a metal, and a metal alloy. In the semiconductor memory device according to some embodiments, the 2D material may be at least one of a metallic material and a semiconductor material. The 2D material may include a 2D allotrope or a 2D compound, and may include, for example, at least one of graphene, molybdenum disulfide (MoS₂), molybdenum diselenide (MoSe₂), tungsten diselenide (WSe₂), and tungsten disulfide (WS₂). The 2D materials discussed above are only listed as an example, and embodiments are not limited thereto.

The cell line capping film 144 may be disposed on the cell conductive line 140. The cell line capping film 144 may extend in the second direction D2 along the upper face of the cell conductive line 140. The cell line capping film 144 may include, for example, at least one of a silicon nitride film, a silicon oxynitride, a silicon carbonitride, and a silicon oxycarbonitride. In the semiconductor memory device according to some embodiments, the cell line capping film 144 may include a silicon nitride film. Although examples are illustrated in which the cell line capping film 144 is a single film, embodiments are not limited thereto.

A bit line contact 146 may be disposed between the cell conductive line 140 and the substrate 100. For example, the cell conductive line 140 may be disposed on the bit line contact 146. For example, the bit line contact 146 may be disposed at a point in which the cell conductive line 140 intersects a central portion of the cell active region ACT having a long island shape. The bit line contact 146 may be disposed between the bit line connecting region of the cell active region ACT and the cell conductive line 140. The bit line contact 146 may be connected to the bit line connecting region.

The plurality of bit line contacts 146 may be disposed along the second direction D2. Each cell conductive line 140 may be disposed on the plurality of bit line contacts 146 and extend along the second direction D2.

The bit line contacts 146 may electrically connect the cell conductive line 140 to the substrate 100. Here, the bit line contacts 146 may correspond to the direct contacts DC. The bit line contacts 146 may include, for example, at least one of an impurity-doped semiconductor material, a conductive silicide compound, a conductive metal nitride, and a metal.

In the region that overlaps the upper face of the bit line contact 146, the cell conductive line 140 may include a second cell conductive film 142 and a third cell conductive film 143. In the region that does not overlap the upper face of the bit line contact 146, the cell conductive line 140 may include first to third cell conductive films 141, 142, and 143.

A cell insulating film 130 may be disposed on the substrate 100 and the element isolation film 105. For example, the cell insulating film 130 may be disposed on the substrate 100 and the element isolation film 105 on which the bit line contact 146 is not formed. The cell insulating film 130 may be disposed between the substrate 100 and the cell conductive line 140, and between the element isolation film 105 and the cell conductive line 140. In the semiconductor memory device according to some embodiments, the upper face of the bit line contact 146 may be higher than the upper face of the cell insulating film 130 on the basis of the upper face of the substrate 100.

Although examples are illustrated in which the cell insulating film 130 is a multi-layer film including a first cell insulating film 131 and a second cell insulating film 132, embodiments are not limited thereto, and in some embodiments the cell insulating film 130 may be a single film. For example, the first cell insulating film 131 may include a silicon oxide film, and the second cell insulating film 132 may include a silicon nitride film, but embodiments are not limited thereto. In some embodiments, the cell insulating film 130 may include three or more insulating films. If the cell insulating film 130 includes a third cell insulating film, the third cell insulating film may be a silicon oxide film.

A cell line spacer 150 may be disposed on the side wall of the cell conductive line 140 and the side wall of the cell line capping film 144. In a portion of the cell conductive line 140 in which the bit line contact 146 is formed, the cell line spacer 150 may be formed on the substrate 100 and the element isolation film 105. The cell line spacer 150 may be disposed on the side wall of the cell conductive line 140, the side wall of the cell line capping film 144, and the side wall of the bit line contact 146.

In a remaining portion of the cell conductive line 140 in which the bit line contact 146 is not formed, the cell line spacer 150 may be disposed on the cell insulating film 130. The cell line spacer 150 may be disposed on the side wall of the cell conductive line 140 and the side wall of the cell line capping film 144.

Although examples are illustrated in which the cell line spacer 150 is a single film, this is only for convenience of explanation, and embodiments are not limited thereto. For example, in some embodiments, the cell line spacer 150 may have a multi-layer film structure. The cell line spacer 150 may include, for example, a silicon oxide film, a silicon nitride film, a silicon oxynitride film (SiON), a silicon oxycarbonitride film (SiOCN), air, and combinations thereof, but embodiments are not limited thereto.

A fence pattern 170 may be disposed on the substrate 100 and the element isolation film 105. The fence pattern 170 may be disposed to overlap the cell gate structure 110 formed inside the substrate 100 and the element isolation film 105. The fence pattern 170 may be disposed on the cell gate capping pattern 113.

The fence pattern 170 may be disposed between the bit line structures 140ST extending in the second direction D2. The fence pattern 170 may include, for example, at least one of silicon oxide, silicon nitride, silicon oxynitride, and combinations thereof.

The plurality of storage contacts 120 may be disposed between the cell conductive lines 140 adjacent to each other in the first direction D1. The storage contacts 120 may be disposed between the fence patterns 170 adjacent to each other in the second direction D2. The storage contacts 120 may overlap the substrate 100 and the element isolation film 105 between the adjacent cell conductive lines 140 in the fourth direction D4. The storage contacts 120 may be connected to the storage connecting region of the cell active region ACT. Here, the storage contacts 120 may correspond to the buried contacts BC.

The storage contacts 120 may include, for example, at least one of an impurity-doped semiconductor material, a conductive silicide compound, a conductive metal nitride, and a metal.

The storage pad 160 may be disposed on each storage contact 120. The storage pad 160 may be electrically connected to the storage contact 120. The storage pad 160 may be connected to the storage connecting region of the cell active region ACT. Here, the storage pad 160 may correspond to the landing pad LP.

The storage pad 160 may overlap a part of an upper face of the cell conductive line 140. The storage pad 160 may include, for example, at least one of an impurity-doped semiconductor material, a conductive silicide compound, a conductive metal nitride, a conductive metal carbide, a metal, and a metal alloy.

A pad isolation insulating film 180 may be disposed on the storage pad 160 and the cell conductive line 140. For example, the pad isolation insulating film 180 may be disposed on the cell line capping film 144. The pad isolation insulating film 180 may define the storage pad 160 that forms a plurality of isolation regions. The pad isolation insulating film 180 may not cover the upper face of the storage pad 160. The pad isolation insulating film 180 may fill the pad isolation recess. The pad isolation recesses may isolate the adjacent storage pads 160.

The pad isolation insulating film 180 may include an insulating material, and may electrically isolate the storage pads 160 from one another. For example, the pad isolation insulating film 180 may include at least one of a silicon oxide film, a silicon nitride film, a silicon oxynitride film, a silicon oxycarbonitride film, and a silicon carbonitride film, but embodiments are not limited thereto.

An upper etching stop film 295 may be disposed on the upper face of the storage pad 160 and the upper face of the pad isolation insulating film 180. The upper etching stop film 295 may include, for example, at least one of silicon nitride (SiN), silicon carbonitride (SiCN), silicon oxycarbonitride (SiOCN), silicon oxycarbide (SiOC), and silicon boronitride (SiBN).

The data storage pattern 190 may be disposed on the storage pad 160. The data storage pattern 190 is connected to the storage pad 160. A part of the data storage pattern 190 may be disposed inside the upper etching stop film 295.

As an example, the data storage pattern 190 may be a capacitor. The data storage pattern 190 may include a lower electrode 191, a capacitor dielectric film 192, and an upper electrode 193. For example, the upper electrode 193 may be a plate upper electrode having a plate shape.

The lower electrode 191 may be disposed on the storage pad 160. The lower electrode 191 may have, for example, a pillar shape. The capacitor dielectric film 192 may be disposed on the lower electrode 191. The capacitor dielectric film 192 may be formed along the profile of the lower electrode 191. The upper electrode 193 may be disposed on the capacitor dielectric film 192. The upper electrode 193 may cover the outer wall of the lower electrode 191, but embodiments are not limited thereto. Although examples are illustrated in which the upper electrode 193 is a single film, this is only for convenience of explanation, and embodiments are not limited thereto. For example, in some embodiments, the lower electrode 191 may have a cylindrical shape with one side open.

Each of the lower electrode 191 and the upper electrode 193 may include at least one of a doped semiconductor material, a conductive metal nitride (e.g., titanium nitride, tantalum nitride, niobium nitride or tungsten nitride), a metal (e.g., ruthenium, iridium, titanium, or tantalum), and a conductive metal oxide (e.g., iridium oxide or niobium oxide), but embodiments are not limited thereto.

The capacitor dielectric film 192 may include, for example one of silicon oxide, silicon nitride, silicon oxynitride, a high dielectric constant material, and combinations thereof, but embodiments are not limited thereto. In the semiconductor memory device according to some embodiments, the capacitor dielectric film 192 may include a stacked film structure in which zirconium oxide, aluminum oxide, and zirconium oxide are sequentially stacked. In the semiconductor memory device according to some embodiments, the capacitor dielectric film 192 may include a dielectric film containing hafnium (Hf). In the semiconductor memory device according to some embodiments, the capacitor dielectric film 192 may have a laminated film structure of a ferroelectric material film and a paraelectric material film.

In contrast, the data storage patterns 190 may be variable resistance patterns that may be switched into two resistance statuses by an electric pulse applied to the memory element. For example, the data storage patterns 190 may include a phase-change material, perovskite compounds, a transition metal oxide, magnetic materials, ferromagnetic materials or antiferromagnetic materials in which a crystalline status changes depending on the amount of current.

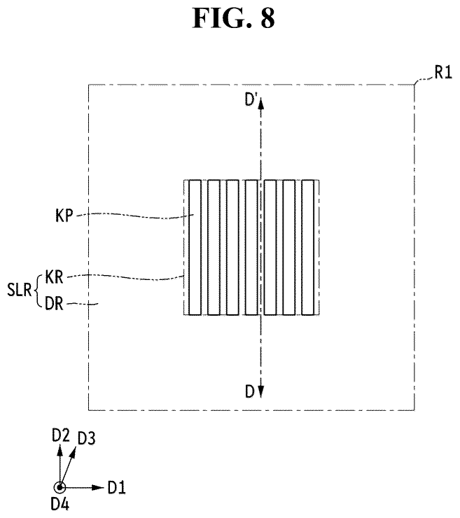

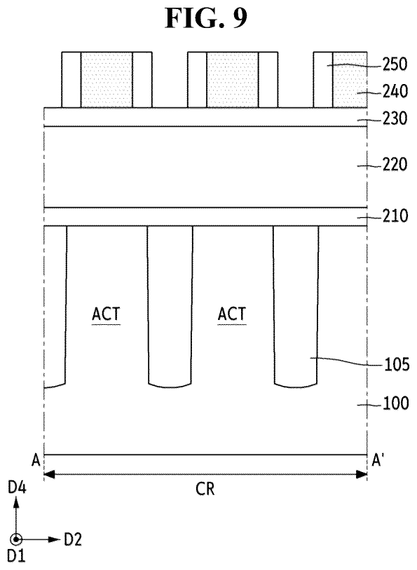

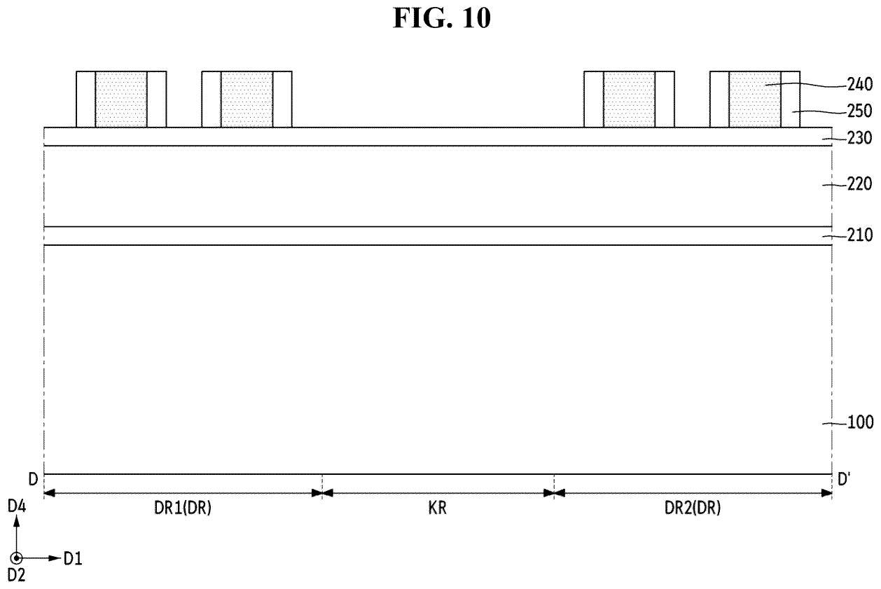

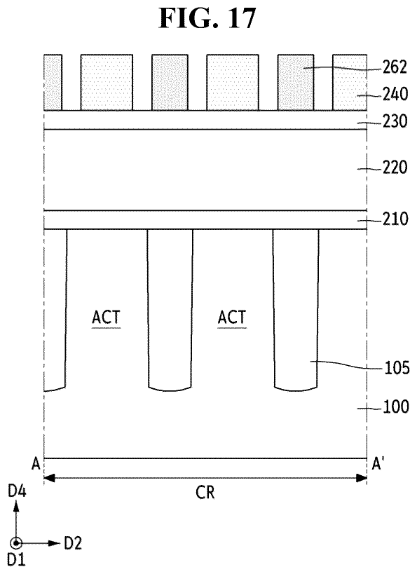

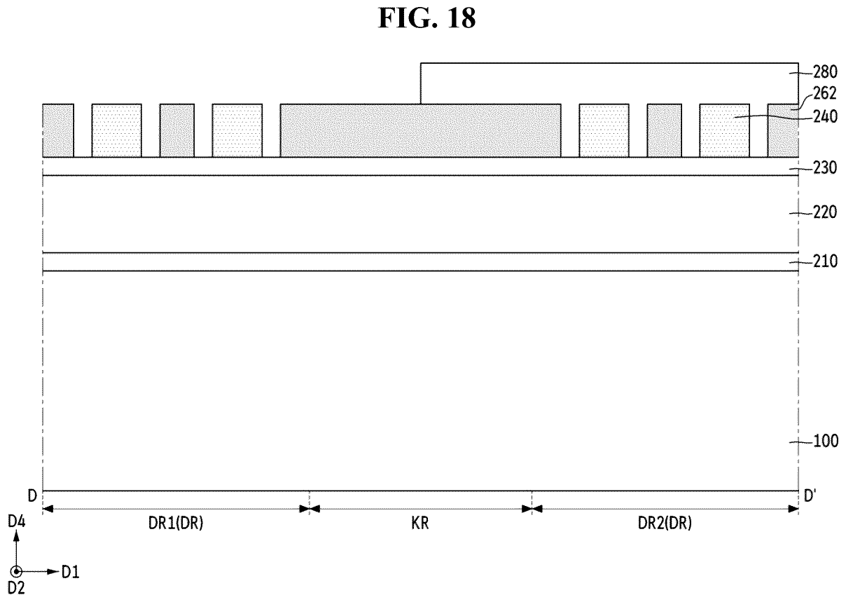

FIGS. 8 to 22 are diagrams for explaining a method for manufacturing a semiconductor device according to some embodiments. For reference, FIG. 8 is an enlarged view of the region R1 of FIG. 2, and FIGS. 10, 12, 14, 16, 18, 20, and 22 are cross-sectional views taken along line D-D′ of FIG. 8.

Referring to FIGS. 8 to 10, a substrate 100 may be provided. The substrate 100 may include an element region ER including a cell region CR and a peripheral region PR, and a scribe lane region SLR including a key region KR and a dummy region DR.

The dummy region DR may include a first dummy region DR1 and a second dummy region DR2. For example, the key region KR may be disposed between the first dummy region DR1 and the second dummy region DR2. The positions and the number of each of the first and second dummy regions DR1 and DR2 are not limited to the examples illustrated in the drawings.

A key pattern KP may be formed on the key region KR of the substrate 100.

The element isolation film 105 may be formed inside the cell region CR of the substrate 100. The element isolation film 105 may define a cell active region ACT. The element isolation film 105 may be formed inside the dummy region DR of the substrate 100. The element isolation film 105 may be formed inside the key region KR of the substrate 100.

An oxide layer 210, a mask layer 220, and an etching stop layer 230 may be sequentially formed on the cell region CR and the scribe lane region SLR of the substrate 100.

The oxide layer 210 may include an oxide such as silicon oxide, but embodiments are not limited thereto. The mask layer 220 may include a carbon-based material, but embodiments are not limited thereto. For example, the mask layer 220 may include a spin-on hard mask (SOH), but embodiments are not limited thereto. For example, the etching stop layer 230 may include a nitride, but embodiments are not limited thereto. For example, the etching stop layer 230 may include SiON, but embodiments are not limited thereto.

A first mask pattern 240 may be formed on the etching stop layer 230 of the cell region CR, the first dummy region DR1, and the second dummy region DR2. The first mask pattern 240 may be not formed on the key region KR to protect the key pattern KP. The first mask pattern 240 may extend, for example, in the first direction D1.

A spacer 250 may be formed on the first mask pattern 240. The spacer 250 may be formed on a side face of the first mask pattern 240.

For example, a preliminary spacer may be formed conformally along the first mask pattern 240 and the etching stop layer 230. The preliminary spacer may be formed using an atomic layer deposition (ALD) process. After the preliminary spacer is formed, the preliminary spacer on the upper face of the first mask pattern 240 and the upper face of the etching stop layer 230 may be removed by an etch-back process. Accordingly, the spacers 250 may be formed on the side face of the first mask pattern 240.

The first mask pattern 240 may include, for example, polysilicon. The spacer 250 may include, for example, oxide.

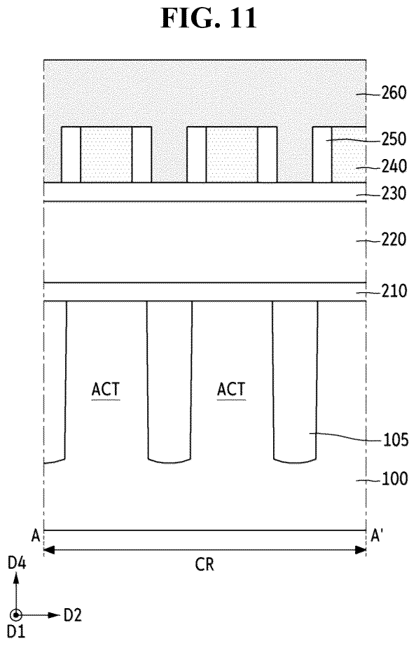

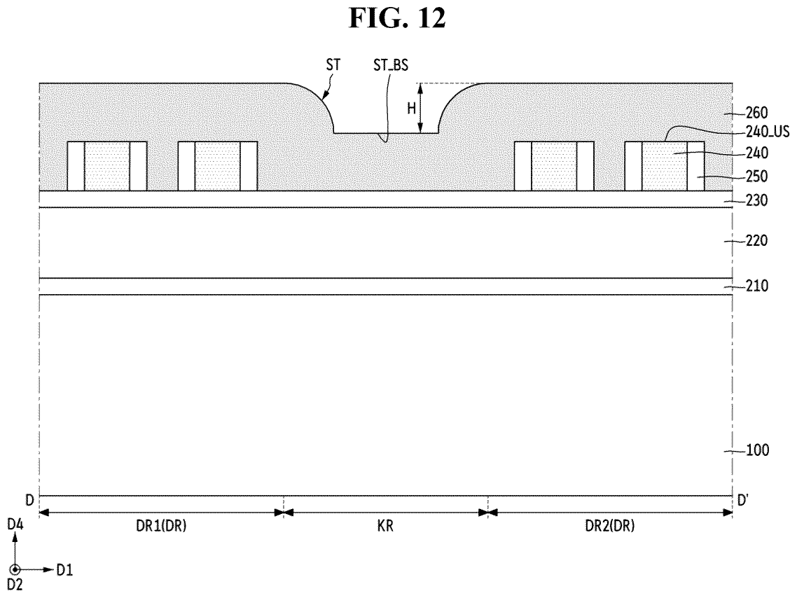

Referring to FIGS. 11 and 12, a mask film 260 may be formed on the etching stop layer 230. The mask film 260 may cover the etching stop layer 230, the first mask pattern 240, and the spacer 250, but embodiments are not limited thereto. The mask film 260 may fill the gap between the spacers 250. The mask film 260 may be formed on the cell region CR, the key region KR, and the dummy region DR.

The mask film 260 includes a stepped portion ST. The stepped portion ST may be formed by the width between adjacent first mask patterns 240. The stepped portion ST may be formed on the key region KR.

For example, a height H of the stepped portion ST may be 400 angstroms (Å). For example, a bottom face ST_BS of the stepped portion ST may be located above an upper face 240_US of the first mask pattern 240.

The mask film 260 may include, for example, polysilicon.

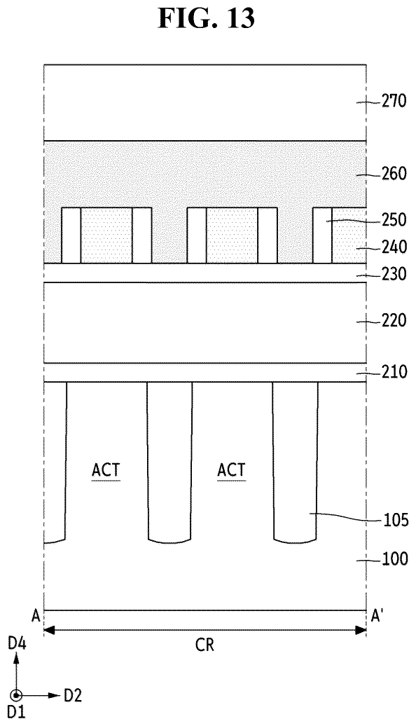

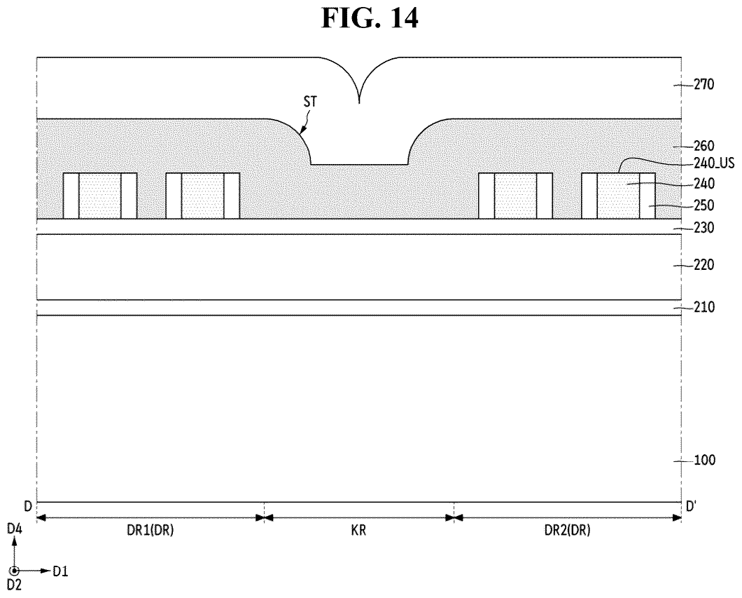

Referring to FIGS. 13 and 14, a sacrificial film 270 that fills the stepped portion ST and covers the mask film 260 may be formed. The sacrificial film 270 may be formed on the cell region CR, the key region KR, and the dummy region DR. The sacrificial film 270 on the stepped portion ST may include a portion that is recessed toward the substrate 100. The recessed portion may be caused by the shape of the stepped portion ST.

The sacrificial film 270 may include an insulating material. For example, the sacrificial film 270 may include an oxide or a nitride, such as TEOS. In some embodiments, the sacrificial film 270 may be a single film. In some embodiments, the sacrificial film 270 may be a multi-layer film.

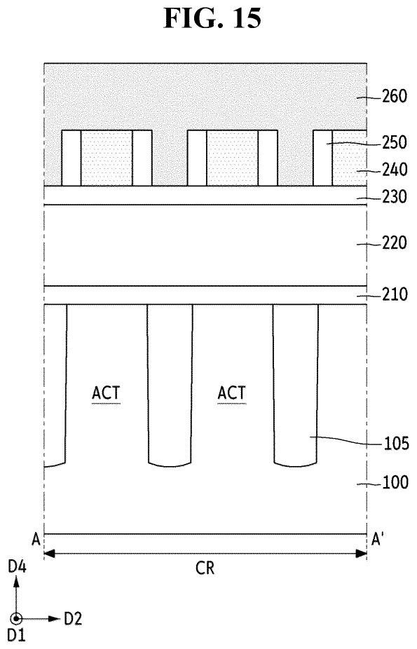

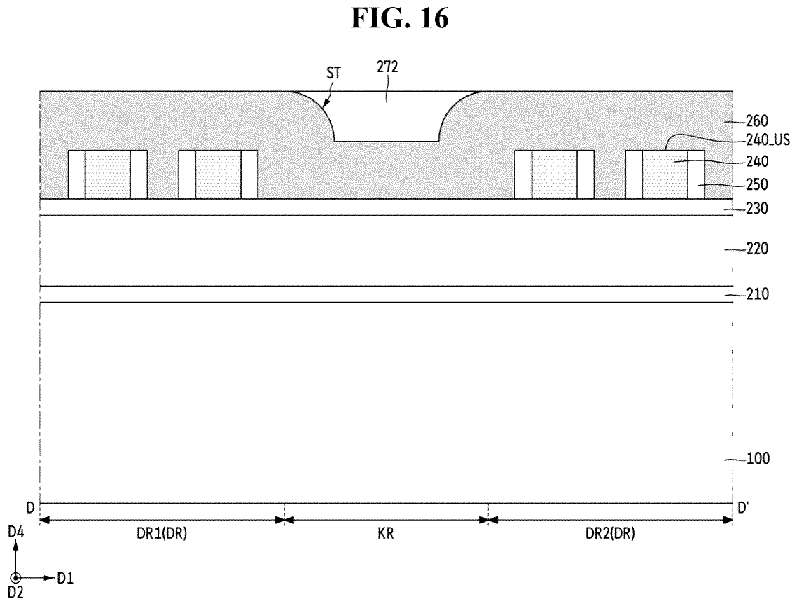

Referring to FIGS. 15 and 16, a planarization process may be performed on the mask film 260 and the sacrificial film 270. For example, a chemical mechanical polishing (CMP) process may be performed on the mask film 260 and the sacrificial film 270. As a result, at least a part of the sacrificial film 270 may be removed. The planarization process may be performed on the sacrificial film 270 to form a sacrificial pattern 272. The sacrificial pattern 272 may be not formed in the remaining region other than the stepped portion ST. At this time, at least a part of the mask film 260 may also be removed. The upper face of the mask film 260 may be substantially coplanar with the upper face of the sacrificial pattern 272.

The process conditions associated with the planarization process may include, for example, a type of slurry, a supply flow rate of slurry, a polishing pressure, a rotational speed, and the like

The slurry may have a selectivity. The selectivity may be a ratio of the amount a specific film quality that is removed when the planarization process is performed using the slurry. For example, the slurry may be made up of a composition that polishes the sacrificial film 270 made of an insulating material to a relatively greater extent, and polishes the mask film 260 made of polysilicon to a relatively lower extent. For example, the selectivity of the insulating film to polysilicon film by the slurry composition may be a ratio of about 2:1 or more.

The supply flow rate of slurry may refer to an amount of supplying slurry required for the planarization process. For example, the slurry may be sprayed through a supply nozzle. The flow rate of the slurry sprayed through the supply nozzle may be selected according to the purpose. For example, the supply flow rate of slurry may be about 50 ml/min to about 1000 ml/min, but embodiments are not limited thereto.

The polishing pressure may refer to the pressure applied when the polishing head is brought into contact with the semiconductor substrate. The polishing pressure may be selected according to the purpose of polishing. For example, the polishing pressure may be about 0.3 pounds per square inch (psi) to about 7 psi, but embodiments are not limited thereto.

The rotational speed may refer to a speed at which the semiconductor substrate and the polishing head rotate while being in contact with each other. According to embodiments, the rotational directions of the semiconductor substrate and the polishing head may be the same direction or opposite directions. The rotational speed of the polishing head may be selected according to the purpose. For example, the rotational speed may be about 10 revolutions per minute (rpm) to about 140 rpm, but embodiments are not limited thereto.

The upper face of the mask film 260 on the cell region CR may have a step due to the first mask pattern 240. The upper face of the mask film 260 may be uneven along the first mask pattern 240. This may cause patterning defects of the cell gate trench 115 which may be formed later. However, in the method for manufacturing a semiconductor device according to some embodiments, planarization may be performed on the mask film 260. Therefore, patterning defects of the cell gate trench 115 may be improved, for example by being reduced or eliminated.

Referring to FIGS. 15 to 18, a second mask pattern 262 may be formed, and the spacer 250 and the sacrificial pattern 272 may be removed.

For example, the mask film 260 may be patterned to form the second mask pattern 262. The second mask pattern 262 may extend long in the first direction D1. The second mask pattern 262 may be formed, for example, by a trimming process.

If the sacrificial pattern 272 is not formed, the mask film 260 of the key region KR may also be patterned due to the stepped portion ST of the mask film 260 when the mask film 260 is patterned. The key pattern KP may also be etched together, and the key pattern KP may be damaged. However, because the stepped portion ST may be filled with the sacrificial pattern 272 in the method for manufacturing the semiconductor device according to some embodiments, the damage of the key pattern KP may be prevented. Therefore, a semiconductor device having improved patterning failure and/or yield may be formed.

Next, a third mask pattern 280 that covers the second dummy region DR2 may be formed. The third mask pattern 280 may fill the gap between the first mask pattern 240 and the second mask pattern 262 of the second dummy region DR2. The third mask pattern 280 may cover the first mask pattern 240 and the second mask pattern 262 of the second dummy region DR2, but embodiments are not limited thereto. The third mask pattern 280 may extend to a part of the key region KR.

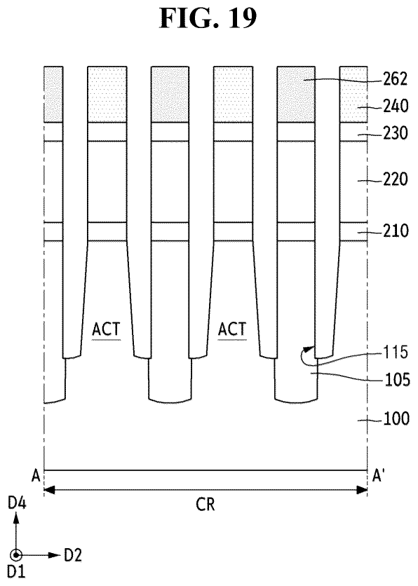

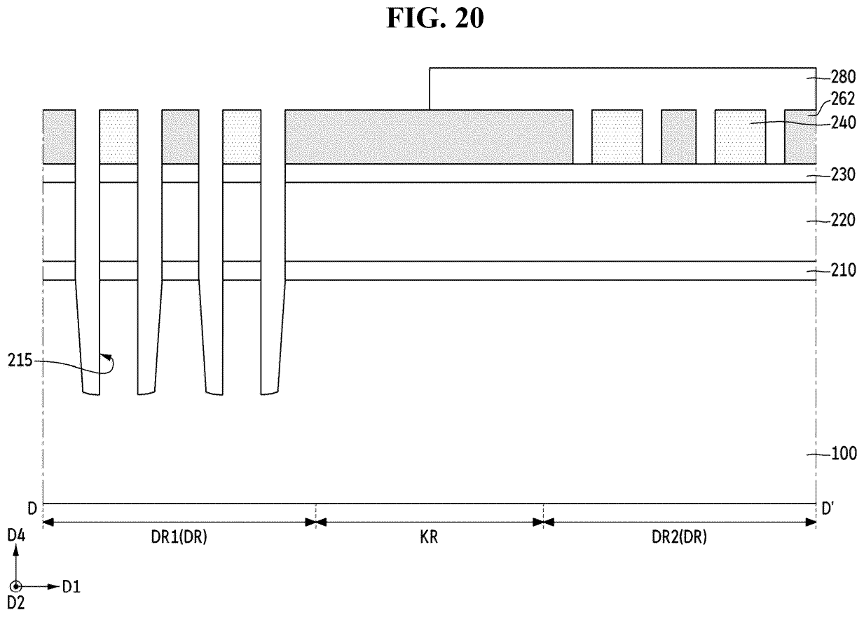

Referring to FIGS. 19 and 20, the cell gate trench 115 and the dummy gate trench 215 may be formed, using the first mask pattern 240 and the second mask pattern 262 as an etching mask. The cell gate trench 115 may be formed by etching the etching stop layer 230, the mask layer 220, the oxide layer 210, and a part of the substrate 100 of the cell region CR. The dummy gate trench 215 may be formed by etching the etching stop layer 230, the mask layer 220, the oxide layer 210, and a part of the substrate 100 of the first dummy region DR1. The cell gate trench 115 and the dummy gate trench 215 may be formed by the same process.

The dummy gate trench 215 may not be formed in the first dummy region DR1 due to the third mask pattern 280. For example, the first dummy region DR1 may be a region that is patterned in a similar way to the cell region CR, and the second dummy region DR2 may be a region that is not patterned in a similar way to the cell region CR.

Next, the first mask pattern 240, the second mask pattern 262, and the third mask pattern 280 may be removed.

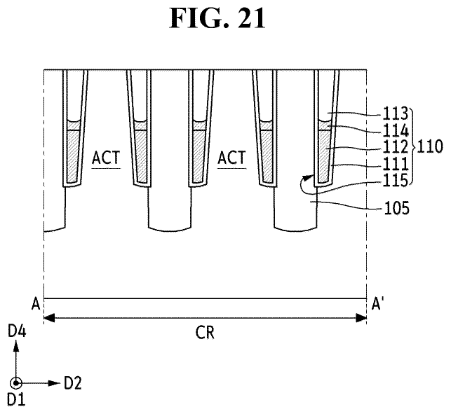

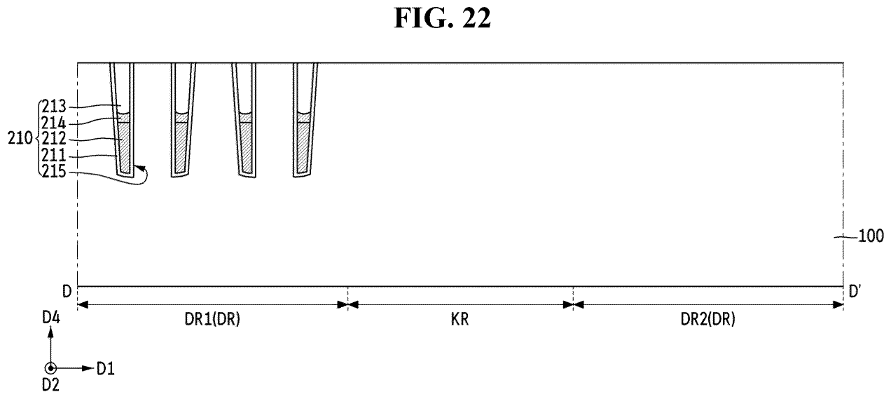

Referring to FIGS. 21 and 22, the cell gate insulating film 111, the cell gate electrode 112, the cell gate capping pattern 113, and the cell gate capping conductive film 114 may be formed inside the cell gate trench 115. The dummy gate insulating film 211, the dummy gate electrode 212, the dummy gate capping pattern 213, and the dummy gate capping conductive film 214 may be formed inside the dummy gate trench 215. Each of the dummy gate insulating film 211, the dummy gate electrode 212, the dummy gate capping pattern 213, and the dummy gate capping conductive film 214 may be formed using the same process as each of the cell gate insulating film 111, the cell gate electrode 112, the cell gate capping pattern 113, and the cell gate capping conductive film 114. Each of the dummy gate insulating film 211, the dummy gate electrode 212, the dummy gate capping pattern 213, and the dummy gate capping conductive film 214 may include the same material as each of the cell gate insulating film 111, the cell gate electrode 112, the cell gate capping pattern 113, and the cell gate capping conductive film 114.

Referring to FIGS. 3 to 7, the cell insulating film 130, the bit line contact 146, the bit line structure 140ST, the storage pad 160, the fence pattern 170, the pad isolation insulating film 180, the upper etching stop film 295, and the data storage pattern 190 may be formed.

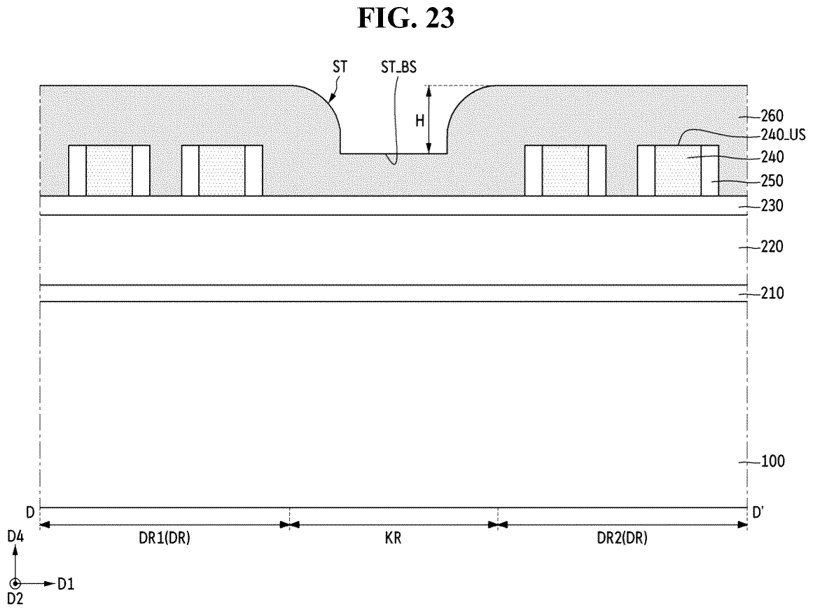

FIG. 23 is a diagram for explaining a method for manufacturing a semiconductor device according to some embodiments. For reference, FIG. 23 is a cross-sectional view taken along D-D′ of FIG. 8, and is a diagram subsequent to FIG. 10.

Referring to FIG. 23, in some embodiments, a bottom face ST_BS of the stepped portion ST may be located above the upper face 240_US of the first mask pattern 240. Next, the manufacturing method described referring to FIGS. 13 to 22 may be implemented.

The present disclosure is not limited to the particular embodiments described above, and may be fabricated in various different forms. Those skilled in the art will appreciate that the present disclosure may be embodied in other specific forms without changing the technical spirit or essential features of the present disclosure. Accordingly, the above-described embodiments should be understood in all respects as illustrative and not restrictive.

What is claimed is:

1. A method for manufacturing a semiconductor device, the method comprising:
providing a substrate comprising an element region and a scribe lane region;
forming a first mask pattern on the element region of the substrate, and a spacer on a side face of the first mask pattern;
forming a mask film that extends along the first mask pattern, the spacer, and the substrate, wherein the mask film comprises a stepped portion on the scribe lane region of the substrate;
forming a sacrificial pattern filling the stepped portion;
forming a second mask pattern by etching the mask film to expose the first mask pattern and the spacer;
removing the spacer and the sacrificial pattern; and
forming a gate trench inside the substrate using the first mask pattern and the second mask pattern as etching masks.

2. The method of claim 1,
wherein the sacrificial pattern comprises an insulating material.

3. The method of claim 1,
wherein the sacrificial pattern comprises a first film, and a second film different from the first film.

4. The method of claim 1, wherein the scribe lane region comprises a key region and a dummy region, and
wherein the stepped portion is formed on the key region.

5. The method of claim 1, wherein the forming of the sacrificial pattern comprises:
forming a sacrificial film on the mask film, wherein the sacrificial film fills the stepped portion, and
performing a planarization process on the mask film and the sacrificial film to form the sacrificial pattern.

6. The method of claim 1, further comprising:
forming a gate electrode inside the gate trench.

7. The method of claim 1, wherein a lowermost face of the stepped portion is above an uppermost face of the first mask pattern.

8. The method of claim 1, wherein a lowermost face of the stepped portion is below an uppermost face of the first mask pattern.

9. A method for manufacturing a semiconductor device, the method comprising:
providing a substrate comprising a scribe lane region, wherein the scribe lane region comprises a first region and a second region;
forming a first mask pattern on the first region of the substrate, and a spacer on a side face of the first mask pattern;
forming a mask film on the first mask pattern, the spacer, and the substrate, wherein the mask film comprises a stepped portion on the second region of the substrate;
forming a sacrificial pattern filling the stepped portion;
patterning the mask film to form a second mask pattern;
removing the sacrificial pattern and the spacer; and
forming a trench inside the substrate using the first mask pattern and the second mask pattern as etching masks.

10. The method of claim 9, wherein the forming of the sacrificial pattern comprises:
forming a sacrificial film on the mask film, wherein the sacrificial film fills the stepped portion, and
performing a planarization process on the mask film and the sacrificial film to form the sacrificial pattern,
wherein the sacrificial film has a selectivity to the mask film in the planarization process.

11. The method of claim 9, further comprising:
forming a key pattern on the second region of the substrate.

12. The method of claim 9,
wherein the scribe lane region further comprises a third region, and
wherein the method further comprises forming the first mask pattern and the spacer on the third region of the substrate.

13. The method of claim 12, further comprising:
after removing the spacer, forming a third mask pattern on the third region wherein the third mask pattern exposes the first region.

14. The method of claim 9, further comprising:
forming a gate electrode inside the trench.

15. The method of claim 9, wherein the sacrificial pattern comprises a material that is different from the mask film.

16. The method of claim 9, wherein the sacrificial pattern comprises an insulating material.

17. A method for manufacturing a semiconductor device, the method comprising:
providing a substrate comprising an element region and a key region;
forming a first mask pattern on the element region of the substrate, and a spacer on a side face of the first mask pattern;
forming a mask film that extends along the first mask pattern, the spacer, and the substrate, wherein the mask film comprises a stepped portion on the key region of the substrate;
forming a sacrificial film filling the stepped portion on the mask film;
performing a planarization process on the sacrificial film and the mask film to form a sacrificial pattern;
patterning the mask film to form a second mask pattern;
removing the sacrificial pattern and the spacer;
forming a third mask pattern on the key region, wherein the third mask pattern exposes the element region;
forming a gate trench inside the substrate using the first mask pattern, the second mask pattern, and the third mask pattern as etching masks;
forming a gate insulating film along the gate trench; and
forming a gate electrode layer and a gate capping layer on the gate insulating film.

18. The method of claim 17,
wherein the mask film comprises polysilicon.

19. The method of claim 17,
wherein the sacrificial film comprises an oxide.

20. The method of claim 17,
wherein the sacrificial film has a selectivity with respect to the mask film in the planarization process.
